(19) United States
(12) Patent Application Publication
(10) Pub. No.: US 2017/0323849 A1
(43) Pub. Date: Nov. 9, 2017

(54) ADAPTER PANEL AND MANUFACTURING METHOD AND ENCAPSULATION STRUCTURE THEREOF AND BONDING METHOD FOR THE ADAPTER PANEL

(71) Applicant: TSINGHUA UNIVERSITY, Beijing (CN)

(72) Inventors: Qian WANG, Beijing (CN); Tiwei WEI, Beijing (CN); Jian CAI, Beijing (CN); Ziyu LIU, Beijing (CN)

(21) Appl. No.: 15/528,049

(22) PCT Filed: Nov. 10, 2015
(86) PCT No.: PCT/CN2015/094218

§ 371 Date: May 18, 2017

(30) Foreign Application Priority Data
Nov. 19, 2014 (CN) 201410665104.4

(51) Int. Cl. H01L 23/498; H01L 21/48; H01L 23/15; H05K 1/14; H05K 3/36

(52) U.S. Cl. CPC H01L 23/49827; H01L 23/49838; H01L 21/486; H01L 23/15; H05K 3/366; H05K 1/144; H01L 21/4853; H01L 23/49833; H01L 23/49816; H05K 2201/042; H05K 2201/10378; H05K 2201/10734

(57) ABSTRACT

Disclosed is an adapter panel and a method of manufacturing the same comprising a panel body having a first surface and an opposing second surface, wherein a through-hole in a frustrum shape is formed through the panel body and filled by a conical electrical conductor between the first and second surface. The conical electrical conductor has a plane end flush with the first surface and a tip end protruding from the second surface. The panel body further comprises a wiring structure on the first surface electrically connected to the plane end of the conical electrical conductor. Bonding to a dielectric plate can be achieved by directly inserting the tip end of the conical electrical conductor into a solder ball.

### TECHNICAL FIELD

The present disclosure relates to the field of encapsulation (also known as packaging), and specifically to an adapter panel and a manufacturing method and encapsulation structure thereof and a bonding method for the adapter panel.

### BACKGROUND

In a three-dimensional system-level integration technique, different chips or subsystems are stacked in the three-dimension scale to form an interconnected structure in the vertical direction. Therefore, as compared with the traditional encapsulation technical, an encapsulation device manufactured using the three-dimensional system-level integration technique has smaller boundary dimension and higher integration density.

In the three-dimensional system-level integration technique, an adapter panel (also known as interposer) between a chipset and a substrate serves to connect. Specifically, the chipset and the substrate are interconnected by means of electrical conductor filled into conducting through-hole of the adapter panel. The adapter panel has the advantages of signal redistribution, heat conduction, passive device integration, etc.

Among methods for forming the through-hole in the adapter panel, laser drilling is widely used due to convenient and efficient drilling.

FIGS. 1a and 1b are schematic views of an adapter panel and an encapsulation structure in the prior art, respectively. As shown in FIG. 1a, the adapter panel 101 may comprise a panel body 201 and electrical conductor in a frustum shape 210, wherein the electrical conductor in a frustum shape 210 may be obtained by drilling conical blind hole within the panel body 201, filling the conical blind hole with electrical conductor and then carrying out a thinning process on the rear surface (i.e., the lower surface of the panel body 201 in FIG. 1a) of the panel body 201. In addition, as shown in FIG. 1b, bonding of an adapter panel 101 to a medium plate 102 is achieved by carrying out the manufacturing process of under bump metal (UBM) 106 on the adapter panel 101 and electrically connecting the adapter panel 101 to the medium plate 102 using solder ball 105, where the process of arranging UBM 106 is a quite complicated process that takes lots of time and cost. Moreover, in such a bonding method, the electrical conductor 210 in the adapter panel 101 have small contact area with the solder ball 105, thus leading to low bonding strength and relatively low bonding reliability.

### SUMMARY OF THE INVENTION

An objective of the present disclosure is to provide an adapter panel which requires no UBM manufacturing process carried out thereon when being bonded to a medium plate, and a manufacturing method and encapsulation structure thereof, and a bonding method for the adapter panel.

To achieve the above objective, the present disclosure provides an adapter panel. The adapter panel comprises: a panel body having a first surface and a second surface which are opposite each other, wherein a through-hole in a frustum shape is formed through the panel body and between the first surface and the second surface; a conical electrical conductor which is filled in the through-hole in a frustum shape, the conical electrical conductor having a plane end and a tip end, wherein the plane end is flush with the first surface and the tip end protrudes from the second surface; and a wiring structure which is arranged on the first surface of the panel body and is electrically connected to the plane end of the conical electrical conductor.

Preferably, the panel body is made of at least one of glass, silicon, silicon carbide and ceramic.

Preferably, the adapter panel further comprises: a passive device and/or a micro-electromechanical system device arranged on the panel body and electrically connected to the wiring structure.

The present disclosure also provides a manufacturing method for an adapter panel. The method comprises: perforating a panel body of an adapter panel to form conical blind hole within the panel body; filling the conical blind hole with conical electrical conductor; carrying out wiring to the panel body from the side of plane end of the conical electrical conductor; thinning the panel body from the side of tip end of the conical electrical conductor until the conical electrical conductor is exposed; and further thinning the panel body from the side of the tip end of the conical electrical conductor, such that the tip end of the conical electrical conductor protrude from the panel body.

The present disclosure also provides an encapsulation structure. The encapsulation structure comprises: the above adapter panel provided according to the present disclosure; a medium plate disposed at the side of the second surface of the panel body; and solder ball located between the second surface of the panel body and the medium plate, wherein the tip end of the conical electrical conductor be inserted into the solder ball and electrically connected to the medium plate by means of the solder ball.

Preferably, the medium plate is a substrate or another adapter panel.

The present disclosure further provides a bonding method for the adapter panel provided by the present disclosure. The method comprises: bonding the protruding tip end of the adapter panel to a medium plate using solder ball, such that the adapter panel is electrically connected to the medium plate.

Preferably, the step of bonding the protruding tip end of the adapter panel to a medium plate using solder ball comprises: arranging the solder ball on the medium plate, wherein position of the solder ball corresponds to the protruding tip end; and inserting the protruding tip end into the corresponding solder ball.

Preferably, the step of bonding the protruding tip end of the adapter panel to a medium plate using solder ball comprises: fixing the solder ball to the protruding tip end; and arranging the solder ball fixed to the protruding tip end on the medium plate.

Preferably, the medium plate is a substrate or another adapter panel.

In the above technical solution, the tip end of the conical electrical conductor may protrude from the adapter panel. Due to this structural feature, in bonding of the adapter panel to the medium plate (for example, a substrate or another adapter panel), the protruding tip end is directly inserted into the solder ball thus to conveniently achieve bonding to the medium plate. In this way, the manufacturing process of UBM does not need to be carried out on the adapter panel, and both time and costs are effectively saved. Furthermore, the contact area between the electrical conductor and the solder ball can be increased by directly inserting the protruding tip end into the solder ball, thus higher bonding strength and higher bonding reliability can be achieved.

Other features and advantages of the present disclosure will be described in detail in the subsequent part of Detailed Description of the Embodiments.

### BRIEF DESCRIPTION OF THE DRAWINGS

Accompanying drawings are intended to provide further understanding of the present disclosure, and constitute a part of the description to explain the present disclosure along with the following specific embodiments, rather than limit the present disclosure, in which:

FIGS. 1a and 1b are schematic views of an adapter panel and an encapsulation structure in the prior art, respectively;

FIGS. 2a and 2b are schematic views of adapter panels provided by two embodiments of the present disclosure;

FIGS. 3a to 3f are schematic views of a manufacturing method for an adapter panel provided by an embodiment of the present disclosure;

FIG. 4 is a schematic view of an encapsulation structure provided by an embodiment of the present disclosure; and

FIGS. 5a and 5b are schematic views of bonding methods for the above adapter panel provided by two embodiments of the present disclosure, respectively.

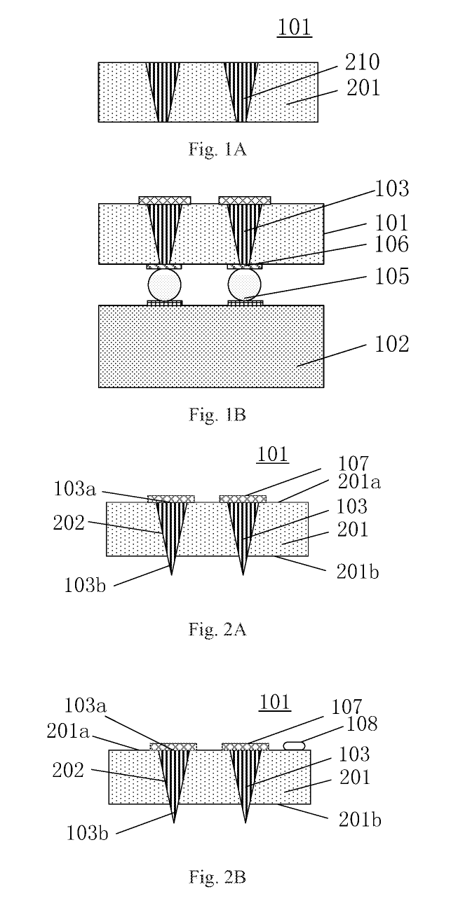

Reference numerals:

| | | |
|---|---|---|
| 101 adapter panel | 102 medium plate | 103 conical electrical |
| | | conductor |
| 103a plane end | 103b tip end | 104 bearing sheet |
| 105 solder ball | 106 under bump | 107 wiring structure |
| | metal | |
| 108 passive device | 201 panel body | 202 through-hole in a |
| | | frustum shape |
| 201a first surface | 201b second surface | 201c conical blind hole |

210 electrical conductor in a frustum shape

### DETAILED DESCRIPTION OF THE EMBODIMENTS

Specific embodiments of the present disclosure will be described below in detail in conjunction with the accompanying figures. It should be understood that the specific embodiments described herein are just intended to illustrate and explain the present disclosure, and not meant to limit the present disclosure.

FIGS. 2a and 2b are schematic views of adapter panels provided by two embodiments of the present disclosure. In the embodiment as shown in FIG. 2a, the adapter panel 101 may comprise a panel body 201, conical electrical conductor 103 and wiring structure 107. The panel body 201 may have a first surface 201a and a second surface 201b which are opposite each other, and through-hole in a frustum shape 202 is formed through the panel body 201 and between the first surface 201a and the second surface 201b. The conical electrical conductor 103 may be filled in the through-hole in a frustum shape 202, and have a plane end 103a and a tip end 103b. The plane end 103a may be flush with the first surface 201a, and the tip end 103b may protrude from the second surface 201b. The wiring structure 107 may be arranged on the first surface 201a of the panel body 201 and be electrically connected to the plane end 103a of the conical electrical conductor 103. Here, the panel body 201 may be made of at least one of glass, silicon, siliconcarbide and ceramic.

It needs to be noted that descriptions are made with an example of two through-holes in a frustum shape 202 and two conical electrical conductors 103 shown in the accompanying drawings for this description. However, it should be understood that the number of the through-hole and that of the electrical conductor herein are merely exemplary and may not be regarded as limitations to the scope of the present disclosure.

It should be understood that the shape of the conical electrical conductor 103 in the accompanying drawings just shows a regular cone shape by way of example, and the cone shape set forth in the present disclosure is not limited to strictly conical structure. For example, the tip end 103b may be of a round head structure that is relatively rounded. Any approximate conical structure that allows implementation of a bonding method which will be described below shall fall into the scope of protection of the present disclosure.

Preferably, in another embodiment as shown in FIG. 2b, in consideration of requirements of circuit functions, the adapter panel 101 may also comprise a passive device 108 and/or a micro-electromechanical system (MEMS) device (descriptions are made with an example of the passive device 108 shown in FIG. 2b). The passive device 108 and/or the MEMS device may be arranged on the panel body 201 and electrically connected to the wiring structure 107 (not shown). Here, the passive device 108, for example, may be a resistor, a capacitor, a filter, a resonator, an optical passive device, or the like.

In FIG. 2b, the passive device 108 is arranged on the first surface 201a of the panel body 201. It will be understood by those skilled in the art that the passive device 108 may also be arranged under the first surface 201a of the panel body 201, i.e., the passive device 108 being implanted within the panel body 201.

It may be understood that only one passive device 108 is used as an example in FIG. 2b, and the number thereof does not have any meaning of limiting the scope of rights of the present disclosure herein. Also, a plurality of passive devices 108 may be arranged in the adapter panel 101.

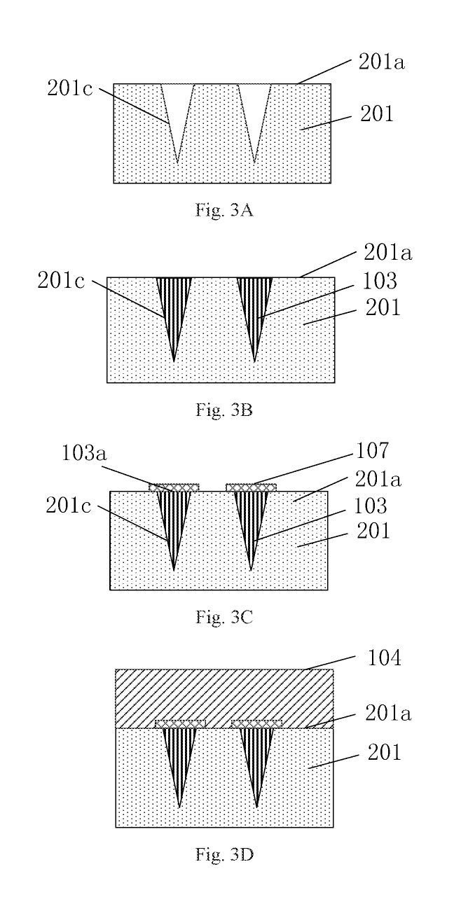

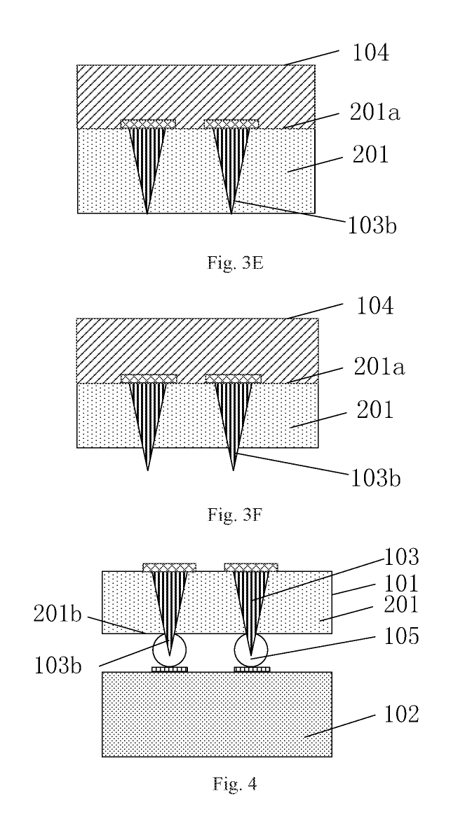

FIGS. 3a to 3f are schematic views of a manufacturing method for an adapter panel 101 provided by an embodiment of the present disclosure.

First, in step 1, as shown in FIG. 3a, the panel body 201 of the adapter panel 101 may be perforated to form conical blind hole 201c within the panel body 201. Technically, the conical blind hole 201c may be drilled in the adapter panel 101 by way of laser drilling.

Next, in step 2, as shown in FIG. 3b, the conical blind hole 201c may be filled with conical electrical conductor 103. For example, the conical blind hole 201c may be filled with copper by way of electroplating to form coppery conical electrical conductor 103.

Next, in step 3, as shown in FIG. 3c, wiring may be carried out to the panel body 201 from the side of the plane end 103a (the upper side of the panel body 201 in FIG. 3c) of the conical electrical conductor 103. In this way, wiring structure 107 may be formed on the wiring side of the panel body 201 and electrically connected with the conical electrical conductor 103. The wiring structure 107 may be used to electrically connect the conical electrical conductor 103 with a passive device (not shown).

Next, in step 4, as shown in FIG. 3d, a bearing sheet 104 may be temporarily bonded to the wiring side of the panel body 201. The bearing sheet 104 may serve to protect the wiring side of the adapter panel 101 in the following thinning process. The step 4 is an optional step for a preferred embodiment, and the following steps may be directly executed by skipping the step 4.

Next, in step 5, as shown in FIG. 3e, the panel body 201 may be thinned from the side of the tip end 103b (the lower side of the panel body 201 in FIG. 3e) of the conical electrical conductor 103 until the conical electrical conductor 103 is exposed.

Next, in step 6, as shown in FIG. 3f, the panel body 201 may be further thinned (for example, by means of dry etching, wet etching or other thinning method) from the side of the tip end 103b of the conical electrical conductor 103, such that the tip end 103b of the conical electrical conductor 103 protrude from the panel body 201.

Finally, on the basis of executing the above step 4 (bonding the bearing sheet 104), in step 7, the bearing sheet 104 may be removed from the wiring side of the panel body 201 to arrange a chip or perform other operations on the wiring side. The adapter panel 101 with the bearing sheet 104 being removed is shown in FIG. 2a.

FIG. 4 is a schematic view of an encapsulation structure provided by an embodiment of the present disclosure. As shown in FIG. 4, the encapsulation structure may comprise the above adapter panel 101 provided by the present disclosure, a medium plate 102 and solder ball 105, wherein the medium plate 102 is disposed at the side of the second surface 201b of the panel body 201. The solder ball 105 is located between the second surface 201b of the panel body 201 and the medium plate 102. The tip end 103b of the conical electrical conductor 103 is inserted into the solder ball 105 and electrically connected to the medium plate 102 by means of the solder ball 105. Here, the medium plate 102 may be a substrate or another adapter panel.

Therefore, in bonding of the adapter panel 101 to the medium plate 102, the protruding tip end 103b may be directly inserted into the solder ball 105, and thus conveniently realizing bonding to the medium plate 102. In this way, UBM arrangement on the adapter panel 101 is avoided, and both time and costs thus are effectively saved. Moreover, as the protruding tip end 103b is directly inserted into the solder ball 105, the contact area between the electrical conductor 103 and the solder ball 105 may also be increased, thus higher bonding strength and higher bonding reliability can be achieved.

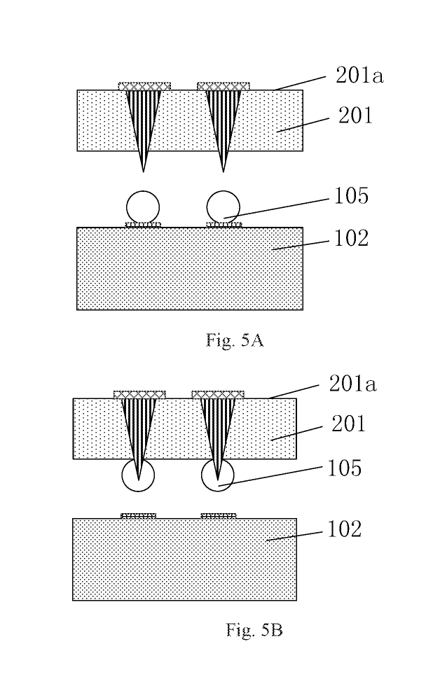

FIGS. 5a and 5b are schematic views of bonding methods for the above adapter panel 101 provided by two embodiments of the present disclosure, respectively. A bonding method for the adapter panel 101 may comprise: bonding the protruding tip end 103b of the adapter panel 101 with a medium plate 102 using solder ball so as to electrically connect the adapter panel 101 to the medium plate 102, wherein the medium plate 102 may be a substrate or another adapter panel.

In one embodiment shown in FIG. 5a, solder ball 105 is arranged on a medium plate 102 first. The position of the solder ball 105 corresponds to the protruding tip end 103b. Subsequently, the protruding tip end 103b is inserted (for example, by way of reflow, hot pressing, etc.) into the corresponding solder ball 105.

In another embodiment shown in FIG. 5b, solder ball 105 is fixed to the protruding tip end 103b first. Subsequently, the solder ball 105 is arranged (for example, by way of reflow, hot pressing, etc.) on a medium plate 102.

Optionally, when the above preferred embodiment (comprising the step 4) is used to manufacture the adapter panel 101, the bearing sheet 104 may also not be removed first, and may be removed after bonding to the medium plate 102 is completed.

Bonding the protruding tip end 103b to the medium plate 102 using the solder ball 105 may be achieved by means of the above two embodiments so as to achieve electrical connection therebetween.

In summary, in the adapter panel, the encapsulation structure and the bonding method for the adapter panel provided by the present disclosure, the tip end 103b of the conical electrical conductor 103 may protrude from the adapter panel 101. Due to this structural feature, in bonding of the adapter panel 101 to the medium plate 102 (for example, a substrate or another adapter panel), the protruding tip end 103b is directly inserted into the solder ball 105 thus to conveniently achieve bonding to the medium plate 102. In this way, the manufacturing process of UBM does not need to be carried out on the adapter panel 101, and both time and costs are effectively saved. Furthermore, the contact area between the electrical conductor 103 and the solder ball 105 may also be increased by directly inserting the protruding tip end 103b into the solder ball 105, thus higher bonding strength and higher bonding reliability can be achieved.

The above are detailed descriptions of the preferred embodiments of the present disclosure in conjunction with the accompanying drawings, but the present disclosure is in no way limited to the specific details in the above embodiments. Various simple variations may be made to the technical solutions of the present disclosure within the scope of the technical concept of the present disclosure, and these simple variations shall all fall into the scope of protection of the present disclosure.

It needs to be additionally noted that various specific technical features described in above specific embodiments may be combined in any appropriate way without conflict. In order to avoid needless repetition, various possible combinations will not be separately explained in the present disclosure.

In addition, various embodiments of the present disclosure may also be combined arbitrarily, and these combinations should be regarded as the disclosure of the present disclosure as long as they do not go against the idea of the present disclosure.

1. An adapter panel, wherein the adapter panel comprising:
a panel body having a first surface and a second surface which are opposite each other, wherein a through-hole in a frustum shape is formed through the panel body and between the first surface and the second surface;
a conical electrical conductor which is filled in the through-hole in a frustum shape, the conical electrical conductor having a plane end and a tip end, wherein the plane end is flush with the first surface and the tip end protrudes from the second surface; the tip end is inserted into a solder ball to electrically connect with a medium plate; and
a wiring structure which is arranged on the first surface of the panel body and is electrically connected to the plane end of the conical electrical conductor.

2. The adapter panel according to claim 1, wherein the panel body is made of at least one of glass, silicon, silicon carbide and ceramic.

3. The adapter panel according to claim 1, wherein the adapter panel further comprises:
a passive device and/or a micro-electromechanical system device arranged on the panel body and electrically connected to the wiring structure.

4. A manufacturing method for an adapter panel, wherein the method comprises:
perforating a panel body of an adapter panel to form conical blind hole within the panel body;
filling the conical blind hole with conical electrical conductor;
carrying out wiring to the panel body from the side of plane end of the conical electrical conductor;
thinning the panel body from the side of tip end of the conical electrical conductor until the conical electrical conductor is exposed; and
further thinning the panel body from the side of the tip end of the conical electrical conductor, such that the tip end of the conical electrical conductor protrudes from the panel body and wherein the tip end is inserted into a solder ball to electrically connect with a medium plate.

5. An encapsulation structure, characterized in that the encapsulation structure comprising:
the adapter panel according to any one of claims 1-3;
a medium plate disposed at the side of the second surface of the panel body; and
a solder ball located between the second surface of the panel body and the medium plate, wherein the tip end of the conical electrical conductor is inserted into the solder ball and electrically connected to the medium plate by means of the solder ball.

6. The encapsulation structure according to claim 5, characterized in that the medium plate is a substrate or another adapter panel.

7. A bonding method for an adapter panel wherein the adapter panel comprises:
a panel body having a first surface and a second surface which are opposite each other, wherein a through-hole in a frustum shape is formed through the panel body and between the first surface and the second surface;
a conical electrical conductor which is filled in the through-hole in a frustum shape, the conical electrical conductor having a plane end and a tip end, wherein the plane end is flush with the first surface and the tip end protruding from the second surface is inserted into a solder ball which is used to electrically connect with a medium plate; and
a wiring structure which is arranged on the first surface of the panel body and is electrically connected to the plane end of the conical electrical conductor;
the method comprising:
bonding the protruding tip end of the adapter panel to a medium plate using solder ball, such that the adapter panel is electrically connected to the medium plate.

8. The method according to claim 7, wherein the step of bonding the protruding tip end of the adapter panel to a medium plate using solder ball comprises:
arranging the solder ball on the medium plate, wherein position of the solder ball corresponds to the protruding tip end; and
inserting the protruding tip end into the corresponding solder ball.

9. The method according to claim 7, wherein the step of bonding the protruding tip end of the adapter panel to a medium plate using solder ball comprises:
fixing the solder ball to the protruding tip end; and
arranging the solder ball fixed to the protruding tip end on the medium plate.

10. The method according to claim 7, wherein the medium plate is a substrate or another adapter panel.

11. The method according to claim 7, wherein the panel body is made of at least one of glass, silicon, silicon carbide and ceramic.

12. The method according to claim 7, wherein the adapter panel further comprising:
a passive device and/or a micro-electromechanical system device arranged on the panel body and electrically connected to the wiring structure.
